(19) United States
(12) Patent Application Publication
(10) Pub. No.: US 2013/0248962 A1
(43) Pub. Date: Sep. 26, 2013

(54) NONVOLATILE SEMICONDUCTOR MEMORY DEVICE AND METHOD OF MANUFACTURING THE SAME

(71) Applicants: Misako Morota, Kanagawa (JP); Hideyuki Nishizawa, Tokyo (JP); Shigeki Hattori, Kanagawa (JP); Masaya Terai, Kanagawa (JP); Koji Asakawa, Kanagawa (JP)

(72) Inventors: Misako Morota, Kanagawa (JP); Hideyuki Nishizawa, Tokyo (JP); Shigeki Hattori, Kanagawa (JP); Masaya Terai, Kanagawa (JP); Koji Asakawa, Kanagawa (JP)

(73) Assignee: Kabushiki Kaisha Toshiba, Tokyo (JP)

(21) Appl. No.: 13/602,523

(22) Filed: Sep. 4, 2012

(30) Foreign Application Priority Data
Mar. 21, 2012 (JP) 2012-063653

(51) Int. Cl. H01L 29/788; H01L 29/66

(52) U.S. Cl. CPC H01L 29/788; H01L 29/66825
USPC 257/315; 438/257

(57) ABSTRACT

A nonvolatile semiconductor memory device of an embodiment includes: a semiconductor layer; an organic molecular layer formed on the semiconductor layer, the organic molecular layer including a plurality of organic molecules, each of the organic molecules includes a tunnel insulating unit of alkyl chain having one end bonded to the semiconductor layer, a charge storing unit, and a bonding unit configured to bond the other end of the alkyl chain to the charge storing unit; a block insulating film formed on the organic molecular layer; and a gate electrode formed on the block insulating film.

### CROSS-REFERENCE TO RELATED APPLICATION

This application is based upon and claims the benefit of priority from Japanese Patent Application No. 2012-063653, filed on Mar. 21, 2012, the entire contents of which are incorporated herein by reference.

### FIELD

Embodiments described herein relate generally to nonvolatile semiconductor memory device and method of manufacturing the nonvolatile semiconductor memory devices.

### BACKGROUND

The main feature of a NAND flash memory as a nonvolatile semiconductor memory device is being a floating-gate (FG) type device having a floating gate that has its basic device structure covered with an insulating film and is made of polysilicon, or being a MONOS (Metal-Oxide-Nitride-Oxide-Silicon)/SONOS (Silicon-Oxide-Nitride-Oxide-Silicon) type that has a charge trapping film formed with a silicon nitride film covered with an insulating film.

Voltage (control voltage) is applied to a control gate formed on the floating gate or the charge trapping film, which serves as a charge storing layer, with an interelectrode insulating film or a block insulating film being interposed between the control gate and the charge storing layer. By controlling the voltage, electrons are injected into the floating gate or the charge trapping film from the substrate via the tunnel insulating film by FN (Fowler-Nordheim) tunneling (writing), or pulling electrons out of the floating gate through the tunnel insulating film (erasing in the FG type and the MONOS/SONOS type), or holes are injected into the charge trapping film to cause annihilation with electrons (assistance for erasing in the MONOS/SONOS type). In this manner, the threshold values of memory cells are varied.

To expand the existing market and create a new market for flash memories, lower power consumption, larger capacities, and higher speeds are required. MOSFETs have been scaled down to realize lower power consumption, larger capacities, and higher speeds, and so have devices of charge storage types. In a device of a charge storage type, the entire layer thickness of the device having a stack structure needs to be reduced, while scaling down is required. Therefore, the film thicknesses of the tunnel insulating film and the charge storage layer are expected to become smaller.

### BRIEF DESCRIPTION OF THE DRAWINGS

FIG. 1 is a cross-sectional view of a memory cell portion of a nonvolatile semiconductor memory device according to a first embodiment;

FIG. 2 is a circuit diagram of the memory cell array of the nonvolatile semiconductor memory device according to the first embodiment;

FIG. 3 is an enlarged cross-sectional view of a memory cell portion of the nonvolatile semiconductor memory device according to the first embodiment;

FIGS. 4A and 4B are diagrams showing example molecular structures of charge storing molecular chains according to the first embodiment;

FIGS. 5A and 5B are diagrams showing example molecular structures of charge storing molecular chains according to the first embodiment;

FIG. 6 is a cross-sectional view illustrating a procedure according to a method of manufacturing the nonvolatile semiconductor memory device of the first embodiment;

FIG. 7 is a cross-sectional view illustrating a procedure according to the method of manufacturing the nonvolatile semiconductor memory device of the first embodiment;

FIG. 8 is a cross-sectional view illustrating a procedure according to the method of manufacturing the nonvolatile semiconductor memory device of the first embodiment;

FIGS. 9A, 9B, and 9C are diagrams for explaining the advantages of the method of manufacturing the nonvolatile semiconductor memory device according to the first embodiment;

FIG. 10 is a diagram showing examples of bonds between the first and second reactive groups in the first embodiment;

FIG. 11 is a cross-sectional view of a memory cell portion of a nonvolatile semiconductor memory device according to a second embodiment;

FIG. 12 is an enlarged cross-sectional view of a memory cell portion of the nonvolatile semiconductor memory device according to the second embodiment;

FIG. 13 is a three-dimensional conceptual diagram of a nonvolatile semiconductor memory device according to a third embodiment;

FIG. 14 is an X-Y cross-sectional view of the nonvolatile semiconductor memory device of FIG. 13;

FIG. 15 is an X-Z cross-sectional view of the nonvolatile semiconductor memory device of FIG. 13;

FIG. 16 is a cross-sectional view illustrating a procedure according to a method of manufacturing the nonvolatile semiconductor memory device of the third embodiment;

FIG. 17 is a cross-sectional view illustrating a procedure according to the method of manufacturing the nonvolatile semiconductor memory device of the third embodiment;

FIG. 18 is a cross-sectional view illustrating a procedure according to the method of manufacturing the nonvolatile semiconductor memory device of the third embodiment;

FIG. 19 is a cross-sectional view illustrating a procedure according to the method of manufacturing the nonvolatile semiconductor memory device of the third embodiment; and

FIG. 20 is a cross-sectional view illustrating a procedure according to the method of manufacturing the nonvolatile semiconductor memory device of the third embodiment.

### DETAILED DESCRIPTION

A nonvolatile semiconductor memory device of an embodiment includes: a semiconductor layer; an organic molecular layer formed on the semiconductor layer, the organic molecular layer including a plurality of organic molecules, each of the organic molecules includes a tunnel insulating unit of alkyl chain having one end bonded to the semiconductor layer, a charge storing unit, and a bonding unit configured to bond the other end of the alkyl chain to the charge storing unit; a block insulating film formed on the organic molecular layer; and a gate electrode formed on the block insulating film.

### First Embodiment

A nonvolatile semiconductor memory device of this embodiment includes: a semiconductor layer; an organic molecular layer formed on the semiconductor layer, the organic molecular layer including a plurality of organic molecules, each of the organic molecules includes a tunnel insulating unit of alkyl chain having one end bonded to the semiconductor layer, a charge storing unit, and a bonding unit configured to bond the other end of the alkyl chain to the charge storing unit; a block insulating film formed on the organic molecular layer; and a gate electrode formed on the block insulating film.

In the nonvolatile semiconductor memory device of this embodiment, the tunnel insulating film and the charge storing layer are formed with organic molecules. Accordingly, the film structure of each memory transistor can be made thinner. Thus, the aspect ratio of the electrode structure of each memory cell is lowered, and microfabrication becomes easier. As the aspect ratio of the electrode structure is lowered, the coupling between adjacent memory cells is reduced, and false operations due to interference between cells are prevented. Thus, the memory cells can be made even smaller, and a scaled down nonvolatile semiconductor memory device can be realized.

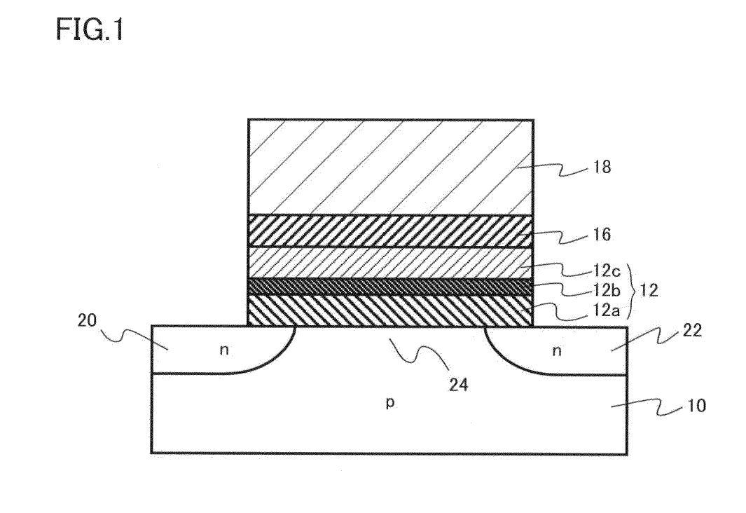

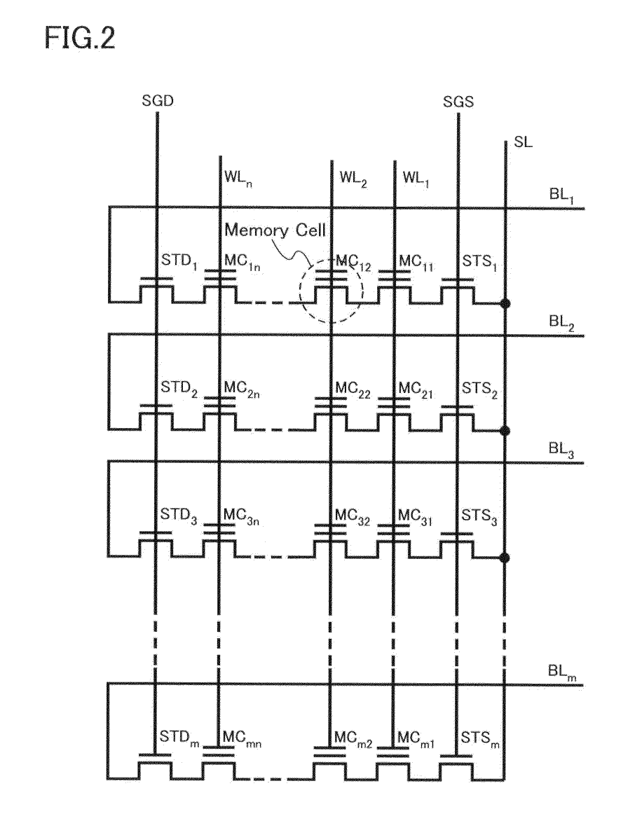

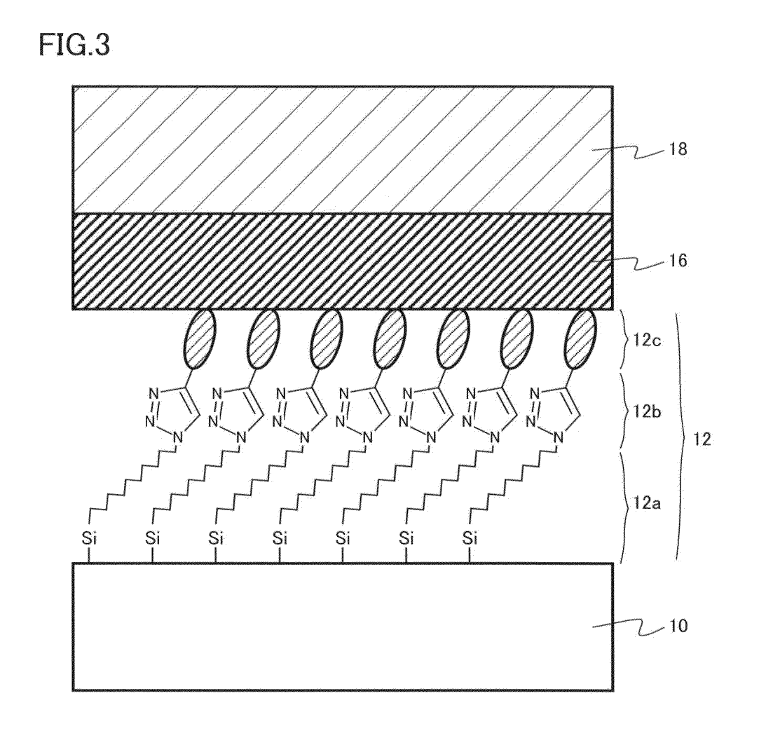

FIG. 1 is a cross-sectional view of a memory cell portion of the nonvolatile semiconductor memory device according to this embodiment. FIG. 2 is a circuit diagram of the memory cell array of the nonvolatile semiconductor memory device according to this embodiment. FIG. 3 is an enlarged cross-sectional view of a memory cell portion of the nonvolatile semiconductor memory device according to this embodiment. The nonvolatile semiconductor memory device of this embodiment is a NAND nonvolatile semiconductor memory device.

As shown in FIG. 2, for example, memory cell transistors MC₁₁˜MC₁ₙ, MC₂₁˜MC₂ₙ, . . . , and MCₘ₁˜MCₘₙ, which are (m×n) transistors (m and n being integers) with floating-gate structures, constitute the memory cell array. In the memory cell array, those memory cell transistors are arranged in the column direction and in the row direction, and are thus arranged in a matrix fashion.

In the memory cell array, for example, the memory cell transistors MC₁₁˜MC₁ₙ and select gate transistors STS₁ and STD₁ are connected in series, to form a NAND string (a memory string) that is a cell unit.

A drain region of the select gate transistor STS₁ for selecting the memory cell transistors MC₁₁˜MC₁ₙ is connected to a source region of the memory cell transistor MC₁₁ located at an end of the row of the memory cell transistors MC₁₁˜MC₁ₙ, which are connected in series. Additionally, a source region of the select gate transistor STD₁ for selecting the memory cell transistors MC₁₁˜MC₁ₙ is connected to a drain region of the memory cell transistor MC₁ₙ located at an end of the row of the memory cell transistors MC₁₁˜MC₁ₙ, which are connected in series.

Select gate transistors STS₂˜STSₘ, the memory cell transistors MC₂₁˜MC₂ₙ, . . . , and MCₘ₁˜MCₘₙ, and select gate transistors STD₂˜STDₘ are also connected in series, to form respective NAND strings.

A common source line SL is connected to the sources of the select gate transistors STS₁˜STSₘ.

The memory cell transistors MC₁₁, MC₂₁, . . . , and MCₘ₁, the memory cell transistors MC₁₂, MC₂₂, . . . , and MCₘ₂, . . . and the memory cell transistors MC₁ₙ, MC₂ₙ, . . . , and MCₘₙ are connected by respective word lines WL₁˜WLₙ, which control the operating voltage to be applied to the gate electrodes.

Additionally, a common select gate line SGS is provided for the select gate transistors STS₁˜STSₘ, and a common select gate line SGD is provided for the select gate transistors STD₁˜STDₘ.

Peripheral circuits (not shown) are formed around the memory cell array illustrated in FIG. 2.

FIG. 1 shows the cross-section of a memory cell in the memory cell array illustrated in FIG. 2, or the memory cell surrounded by a dashed line in FIG. 2, for example. In this embodiment, the transistors of the memory cells are n-type transistors having electrons as carriers, for example.

The memory cells are formed on a p-type silicon semiconductor layer 10 containing p-type impurities, for example. An organic molecular layer 12 is provided on the silicon semiconductor layer 10, a block insulating film 16 is provided on the organic molecular layer 12, and a gate electrode 18 is provided on the block insulating film 16. On both sides of the gate electrode 18, a source region 20 and a drain region 22 are formed in the semiconductor layer 10. The region located below the gate electrode 18 in the semiconductor layer 10 serves as a channel region 24. The channel region 24 is interposed between the source region 20 and the drain region 22.

As shown in FIG. 3, the organic molecular layer 12 includes a tunnel insulating region 12a, a bonding region 12b, and a charge storing region 12c. The organic molecular layer 12 includes a plurality of organic molecules. The organic molecular layer 12 has tunnel insulating region 12a bonding region 12b on the insulating region 12a, and charge storing region 12c on the bonding region 12b. Each of the organic molecules includes a tunnel insulating unit belonging to the tunnel insulating region 12a, a bonding unit belonging to the bonding region 12b, and charge storing unit belonging to the charge storing region 12c. The tunnel insulating unit including an alkyl chain having one end bonded to the semiconductor layer and a bonding unit bonding the other end of the alkyl chain to the charge storing unit. The organic molecular layer 12 is preferably a monomolecular layer, so as to have a smaller thickness and restrain variations in characteristics among the memory cells by achieving uniform characteristics.

The film thickness of the organic molecular layer 12 is 2 to 3 nm, for example.

Here, the charge storing region 12c has a function to actively store charges as memory cell information. When writing or erasing is performed on a memory cell, the tunnel insulating region 12a functions as an electron/hole transfer pathway between the channel region 24 in the semiconductor layer 10 and the charge storing region 12c through a tunneling phenomenon. At the time of reading or standing by, the tunnel insulating region 12a has a function to restrain electron/hole transfers between the channel region 24 and the charge storing region 12c. The block insulating film 16 is a so-called interelectrode insulating film, and has a function to block the electron/hole flow between the charge storing region 12c and the gate electrode 18.

One end of each of the alkyl chains forming the tunnel insulating region 12a is bonded to the semiconductor layer 10. The film thickness of the tunnel insulating region 12a is approximately 1.5 to 2 nm, for example.

The alkyl chains are formed as a self-assembled monolayer on the semiconductor layer 10, for example, and is a high-density film. The wave functions of the alkyl chains spread only in the bonding direction, and the wave functions do not spread in the thickness direction or in a direction perpendicular to the surface of the semiconductor layer 10. Accordingly, the tunneling probability proportional to overlaps among the wave functions becomes small.

Additionally, the constituent atoms are smaller than those in a silicon oxide film, for example, and the outermost electron orbital is smaller. Accordingly, the spread of the wave functions becomes narrower. As a result, the tunneling probability proportional to overlaps among the wave functions becomes smaller than that in a silicon oxide film in principle.

The tunneling current I proportional to the tunneling probability exponentially decreases with respect to the length L of the alkyl chains, or varies as indicated by the following formula:

I∝exp (−αL) [Formula 1]

where α is 0.12 (nm⁻¹) in the alkyl chains. Accordingly, when the number of C—C bonds increases by two, the tunneling current can be reduced by almost one digit. That is, by increasing the number of C—C bonds and increasing the alkyl chain length, charge release from the charge storing region 12c can be reduced.

Further, the alkyl chains of the self-assembled monolayer are formed at an angle to the substrate. Therefore, when the alkyl chain length is increased, the thickness of the tunnel insulating region 12c increases by the amount equivalent to the product of the alkyl chain length and the sine of the angle to the substrate. Accordingly, the insulation properties are improved, without an excess increase in the film thickness.

For the above reasons, the tunnel insulating region 12a is formed with alkyl chains, particularly with alkyl chains formed as a self-assembled monolayer. In this manner, higher insulation properties than in a silicon oxide film of the same film thickness, for example, can be secured. Accordingly, the tunnel insulating region 12a can be made thinner than in a case where a silicon oxide film is used.

The number of carbons in each of the alkyl chains is preferably not smaller than 6 and not larger than 30, or more preferably, not smaller than 10 and not larger than 20. If the number of carbons is below the above mentioned range, the insulation properties might become lower. If the number of carbons is beyond the above mentioned range, the film thickness might become greater, resulting in difficulties in scaling down. The number of carbons in each of the alkyl chains is more preferably 18, because a self-assembled film can be stably manufactured with such a number of carbons.

The permittivity of the alkyl chains is approximately 2 to 3, which is higher than that of vacuum. Accordingly, the electric field applied to the insulating region is smaller than in vacuum. Therefore, the FN (Fowler-Nordheim) tunneling probability is made lower, compared with vacuum. As the alkyl chain density becomes higher, and the gaps (vacuum) among the alkyl chains become narrower, the insulation properties of the insulating region 12a become higher. In view of this, it is preferable to form the alkyl chains as a self-assembled monolayer.

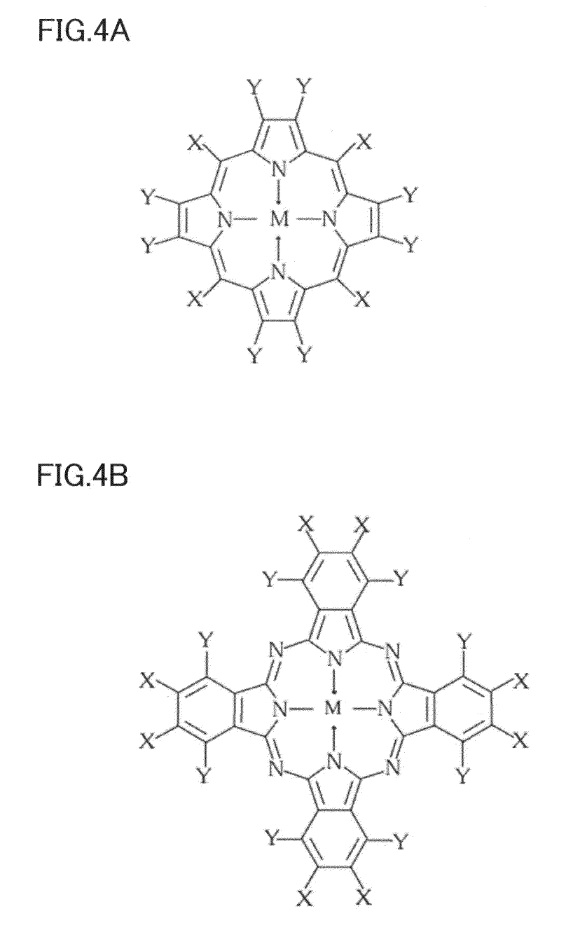

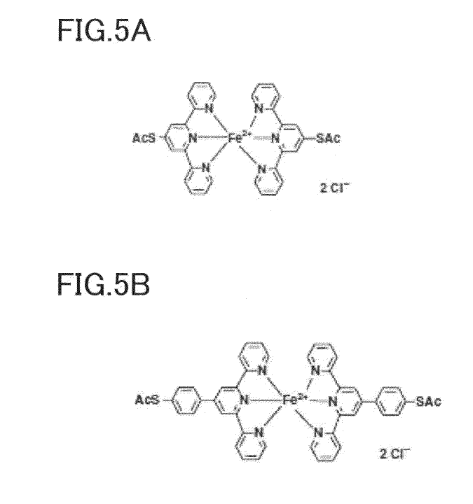

The charge storing region 12c is formed with charge storing molecular chains having a function to store charges. FIGS. 4A and 4B, and FIGS. 5A and 5B are diagrams showing the molecular structures of charge storing molecular chains according to this embodiment.

FIG. 4A shows a metal porphyrin and a derivative thereof. In the drawing, M represent a metal atom or a metal compound, such as zinc (Zn), iron (Fe), cobalt (Co), nickel (Ni), or copper (Cu). In the drawing, X and Y represent hydrogen atoms, halogen atoms, or electron-withdrawing substituents such as cyano groups, carbonyl groups, or carboxyl groups.

FIG. 4B shows a metal phthalocyanine and a derivative thereof. In the drawing, M represent a metal atom or a metal compound, such as copper (Cu), cobalt (Co), iron (Fe), nickel (Ni), titanium oxide (TiO), aluminum chloride (AlCl). In the drawing, X and Y represent hydrogen atoms, halogen atoms, or electron-withdrawing substituents such as cyano groups, carbonyl groups, or carboxyl groups.

FIGS. 5A and 5B show bis-terpyridine metal complexes. In the drawings, the central metal atom is iron (Fe), for example. However, the central metal atom may be manganese (Mn), cobalt (Co), zinc (Zn), or ruthenium (Ru), for example.

The bonding unit bonds the other end of each alkyl chain, which is not bonded to the semiconductor layer 10, to the charge storing unit. For example, the bonding unit is a triazole ring, as shown in FIG. 3.

The organic molecular layer 12 preferably has a high thermal stability. As for the charge storing molecular chains, for example, the decomposition temperatures of porphyrins, phthalocyanines, and terpyridine metal complexes are 500 to 600° C., and the charge storing molecular chains have high thermal stabilities accordingly.

Additionally, the bonds between the semiconductor layer 10 and derivatives of silyl groups, which can be applied to the bonds between the semiconductor layer 10 and the alkyl chains, for example, are the same as O—Si—O bonds of SiO₂, and have a high thermal stability. As for the bonding region 12b, for example, the decomposition temperature of the triazole rings is about 500° C. in a non-oxidizing atmosphere, and the triazole rings have a high thermal stability.

The block insulating film 16 is a metal oxide such as a hafnium oxide, a silicon oxide, or an aluminum oxide. The gate electrode 18 is polycrystalline silicon having impurities introduced thereinto, and has conductive properties. The source region 20 and the drain region 22 are formed with n-type diffusion layers containing n-type impurities, for example.

Next, a method of manufacturing the nonvolatile semiconductor memory device according to this embodiment is described. The method of manufacturing the nonvolatile semiconductor memory device according to this embodiment includes: bonding one end of each of alkyl chains to a semiconductor layer in a self-assembling manner, each of the alkyl chains having a first reactive group at the other end thereof; forming a charge storing region by bonding charge storing molecular chains having second reactive groups to the alkyl chains through reactions between the first reactive groups and the second reactive groups; forming a block insulating film on the charge storing region; and forming a gate electrode on the block insulating film.

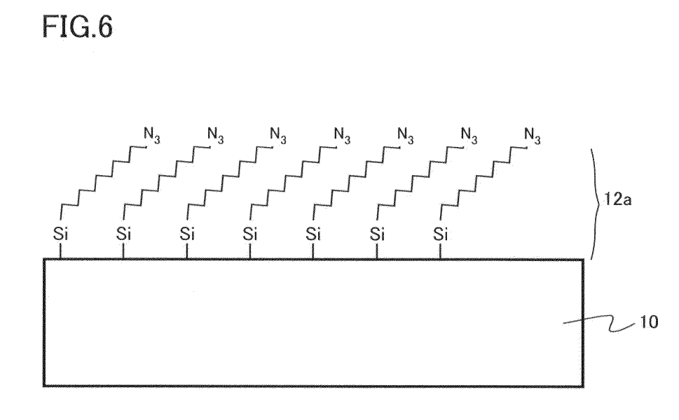

FIGS. 6 through 8 are cross-sectional views illustrating the process according to the method of manufacturing the nonvolatile semiconductor memory device of this embodiment.

Alkyl chains each having an azido group (—N₃) as the first reactive group at one end and a derivative of a silyl group at the other end, such as —SiCl₃, are prepared. The —SiCl₃ of the alkyl chains are bonded to the semiconductor layer 10 in a self-assembling manner. In this manner, the tunnel insulating region 12a is formed with a self-assembled monolayer (SAM) of the alkyl chains (FIG. 6). Either a liquid phase technique or a gas phase technique may be used in bonding the alkyl chains. Additionally, a silicon oxide film may be formed on the semiconductor layer 10 through thermal oxidation, for example, prior to the formation of the SAM.

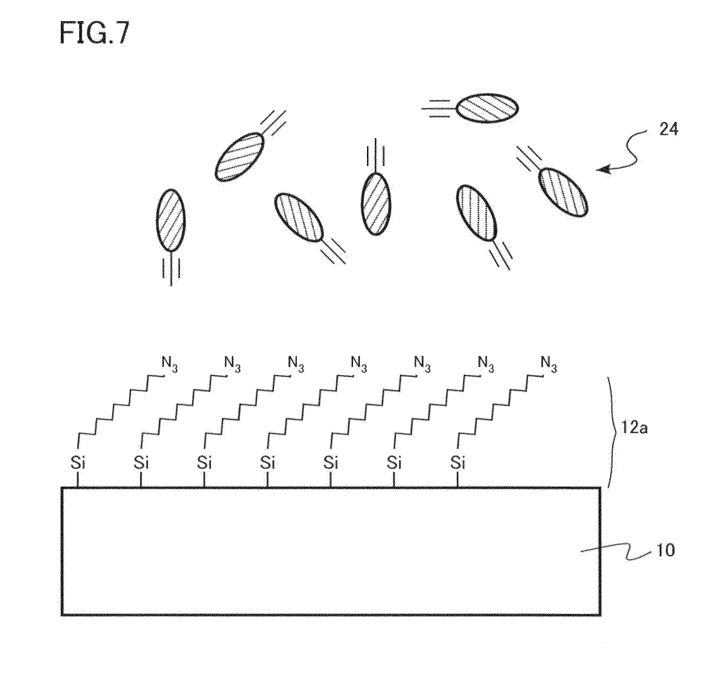

The charge storing molecular chains 24 having ethynyl groups (—C≡CH) as the second reactive groups, such as porphyrins, are then prepared. The semiconductor layer 10 is immersed in a solution of the charge storing molecular chains 24 (FIG. 7).

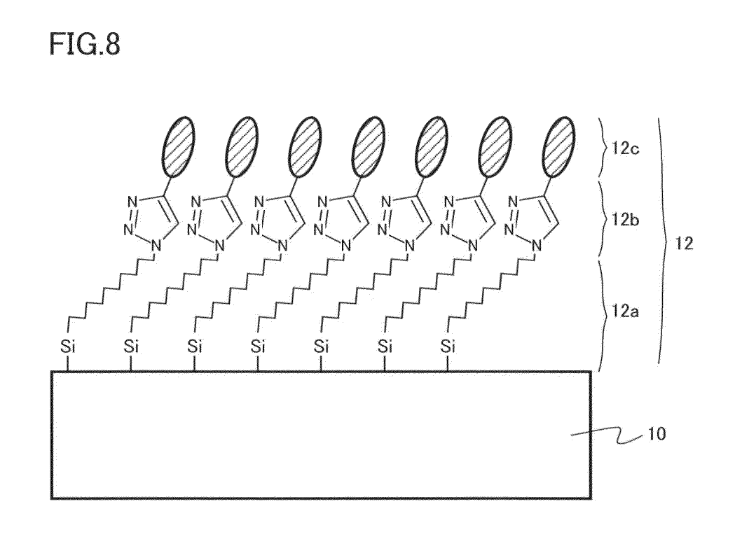

A Huisgen reaction is caused between the azido groups (the first reactive groups) of the alkyl chains and the ethynyl groups (the second reactive groups) of the charge storing molecular chains 24, so that the charge storing molecular chains 24 are bonded to the alkyl chains. In this manner the charge storing region 12c is formed. Through the above procedures, the organic molecular layer 12 including the tunnel insulating region 12a of the alkyl chains, the bonding region 12b of triazole rings, for example, and the charge storing region 12c of porphyrins, for example, is formed (FIG. 8).

After that, a hafnium oxide film is deposited on the charge storing region 12c of the organic molecular layer 12 by ALD (Atomic Layer Deposition), for example, to form the block insulating film 16.

An impurity-doped polycrystalline silicon film is then formed by CVD (Chemical Vapor Deposition), for example, to form the gate electrode 18. By patterning the stacked films, a gate electrode structure is formed.

With the gate electrode 16 serving as a mask, n-type impurity ions are then implanted, to form the source region 20 and the drain region 22, for example. In this manner, the nonvolatile semiconductor memory device illustrated in FIGS. 1 and 3 can be manufactured.

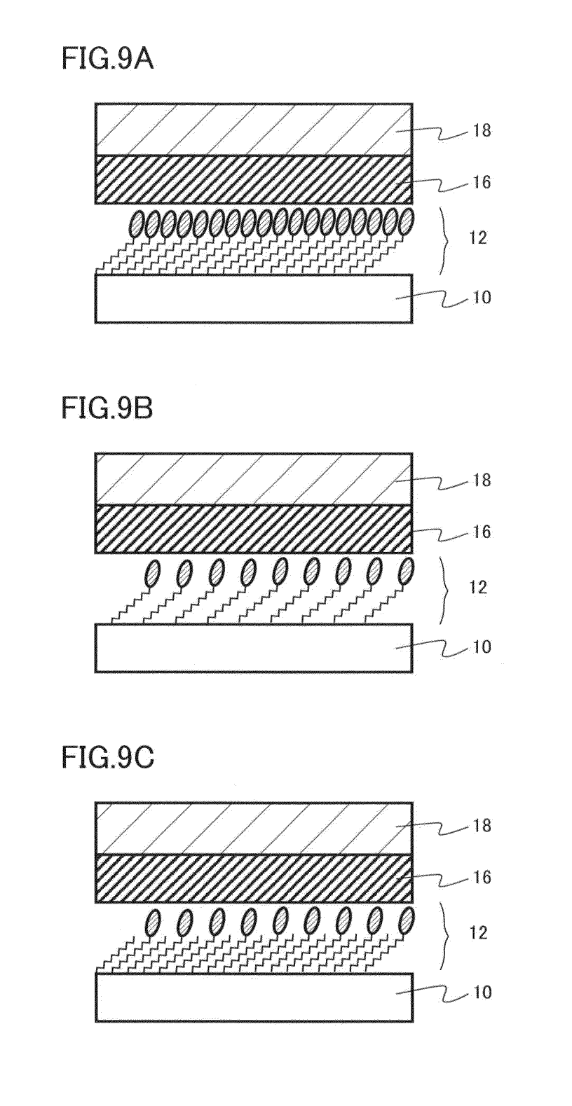

FIGS. 9A, 9B, and 9C are diagrams for explaining the advantages of the method of manufacturing the nonvolatile semiconductor memory device according to this embodiment. In this embodiment, the tunnel insulating region 12a of alkyl chains is first formed on the semiconductor layer 10 in a self-assembling manner, with the charge storing molecular chains not being bonded. As a result, a high-density and uniform self-assembled monolayer of alkyl chains can be formed, as shown in FIG. 9A.

An example case where alkyl chains are formed on the semiconductor layer 10 in a self-assembling manner while the charge storing molecular chains are bonded is now described. In this case, due to the size or interaction of the charge storing molecular chains, the density of the alkyl chains does not become higher, as shown in FIG. 9B.

Since the alkyl chains are bonded while the charge storing molecular chains are not bonded, the density of the alkyl chains becomes higher in this embodiment. Accordingly, the tunnel insulating region 12a can have high insulation properties.

As shown in FIG. 9C, in this embodiment, there might be cases where the bond density of the charge storing molecular chains with respect to the alkyl chains is controlled and is actively lowered, or where the bond density does not become higher due to the size or interaction of the charge storing molecular chains, for example. Even in such cases, the tunnel insulating region 12a with high insulation properties can be formed by the manufacturing method according to this embodiment.

Additionally, in this embodiment, the first reactive groups of the alkyl chains and the second reactive groups of the charge storing molecular chains are bonded, so that the alkyl chains and the charge storing molecular chains are bonded. In a case where the first reactive groups are azido groups, and the second reactive groups are ethynyl groups, the binding reaction is called a Huisgen reaction.

A Huisgen reaction is a reaction having high reactivity, selectivity, and stability. A technique of forming a new functional molecule by bonding molecules through such a reaction is called quick chemistry. In this embodiment, the technique of quick chemistry is used, to increase the density of the charge storing molecular chains in the charge storing region 12c, and form the stable charge storing region 12c. Accordingly, memory cells that have a large charge storage amount and excellent reliability can be formed.

The first reactive groups and the second reactive groups are not limited to azido groups and ethynyl groups, but may be ethynyl groups and azido groups.

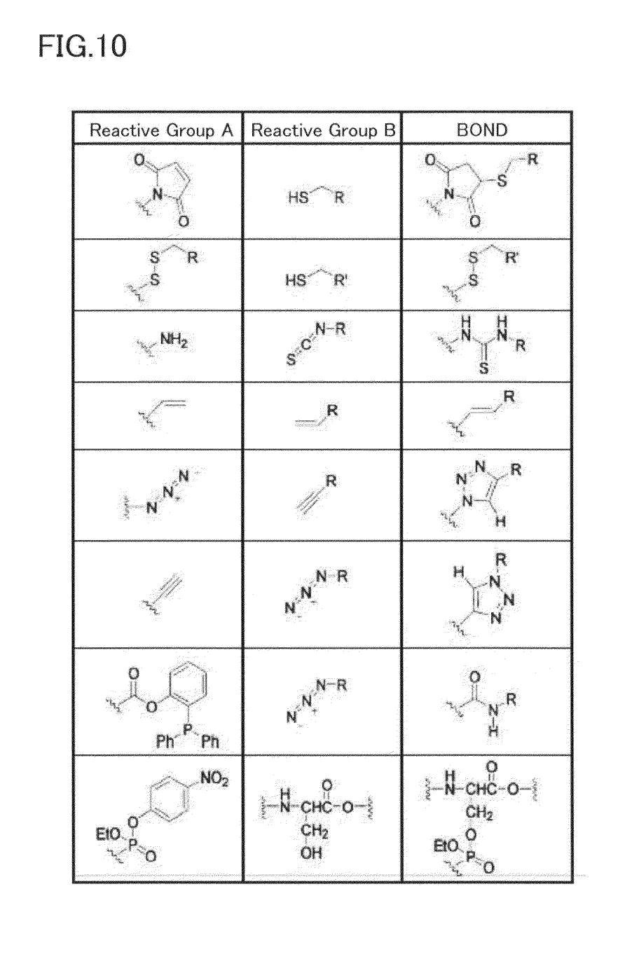

FIG. 10 is a diagram showing examples of bonds between first and second reactive groups of this embodiment. The molecular structures of bonds formed through reactions between first reactive groups and second reactive groups are shown. The reactive group A, the reactive group B, and the bond shown in each row is a combination of a first reactive group (or a second reactive group), a second reactive group (or a first reactive group), and a bond. In this embodiment, the combinations shown in FIG. 10 can also be used.

The reactive group at the opposite end of each alkyl chain from the azido group (the first reactive group) is not limited to —SiCl₃, and may be some other reactive group such as —Si(OMe)₃ or —SiOH, as long as the reactive group can be bonded to the semiconductor layer 10.

As described above, this embodiment can provide a scaled down nonvolatile semiconductor memory device and a method of manufacturing the nonvolatile semiconductor memory device through reductions in the film thicknesses of the tunnel insulating film and the charge storing layer.

### Second Embodiment

A nonvolatile semiconductor memory device of this embodiment is the same as that of the first embodiment, except that the organic molecular layer includes a block insulating region having the function of the block insulating film. Therefore, the same explanations as those in the first embodiment will not be repeated.

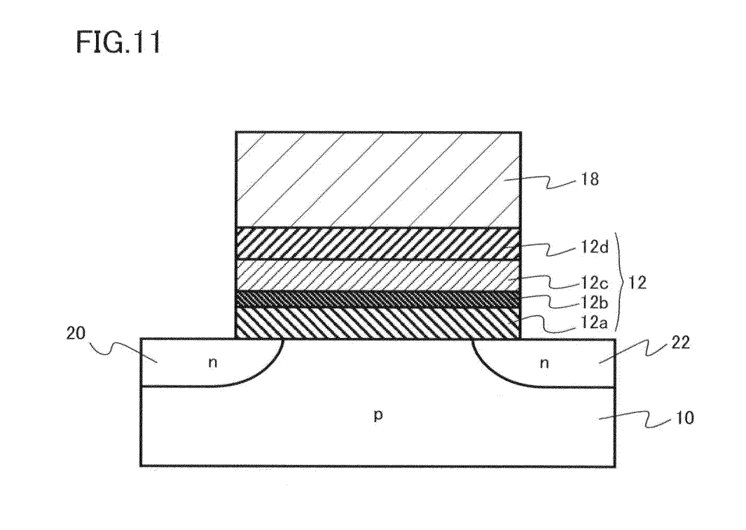

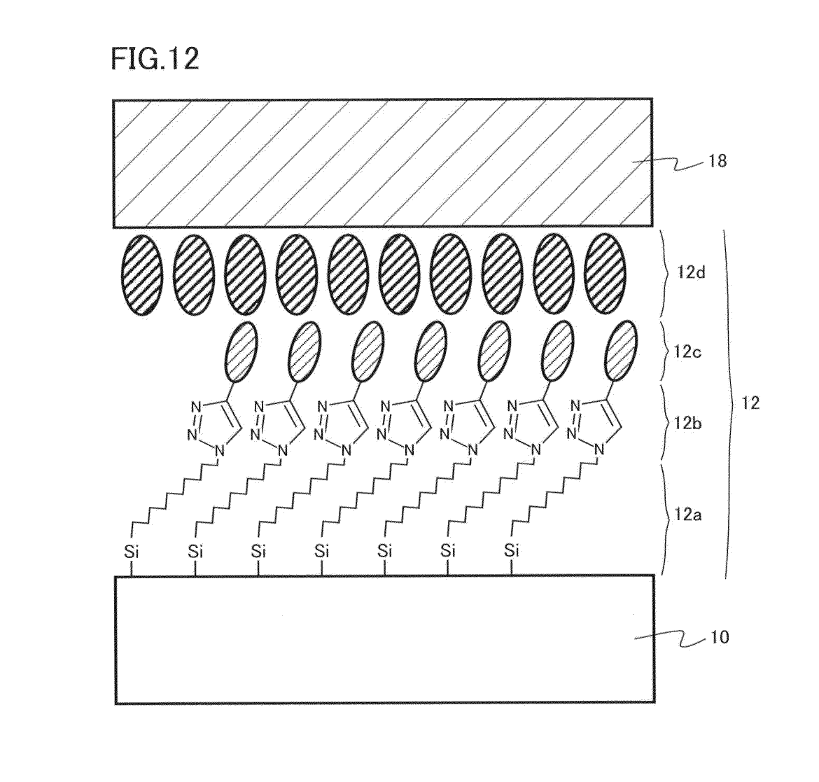

FIG. 11 is a cross-sectional view of a memory cell portion of the nonvolatile semiconductor memory device according to this embodiment. FIG. 12 is an enlarged cross-sectional view of a memory cell portion of the nonvolatile semiconductor memory device according to this embodiment.

The memory cells are formed on a p-type silicon semiconductor layer 10 containing p-type impurities, for example. An organic molecular layer 12 is provided on the silicon semiconductor layer 10, and a gate electrode 18 is provided on the organic molecular layer 12. On both sides of the gate electrode 18, a source region 20 and a drain region 22 are formed in the semiconductor layer 10. The region located below the gate electrode 18 in the semiconductor layer 10 serves as a channel region 24. The channel region 24 is interposed between the source region 20 and the drain region 22.

As shown in FIG. 12, the organic molecular layer 12 includes a tunnel insulating region 12a of alkyl chains each having one end bonded to the semiconductor layer 10, a charge storing region 12c, a bonding region 12b bonding the other end of each of the alkyl chains to the charge storing region 12c, and a block insulating region 12d formed on the charge storing region 12c. The organic molecular layer 12 is preferably a monomolecular layer, so as to have a smaller thickness and restrain variations in characteristics among the memory cells by achieving uniform characteristics.

The block insulating region 12d has a function to block the electron/hole flow between the charge storing region 12c and the gate electrode 18. The block insulating region 12d contains block insulating molecules or block insulating molecular chains with a larger molecular weight than that of the alkyl chains forming the tunnel insulating region 12a. The block insulating region 12d increases the ability to block electron/hole transfers by containing molecules or molecular chains with a larger molecular weight than that of the alkyl chains. The block insulating molecules or block insulating molecular chains with the greater molecular weight than that of the alkyl chains are preferably formed with heavier elements than carbon and hydrogen, which form the alkyl chains.

The molecular weight of the molecules or molecular chains contained in the block insulating region 12d can be measured by measuring the molecules in the organic molecular layer 12 with a mass spectrometer, for example.

The block insulating region 12d may contain block insulating organic molecules that do not bind to the charge storing molecular chains of the charge storing region 12c, or molecular chains that bind to the charge storing molecular chains of the charge storing region 12c.

The block insulating molecules or block insulating molecular chains contained in the block insulating region 12d may be alkyl halide molecules or molecular chains with a high dipole moment, for example. More specifically, —[CF₂—CF₂]ₙ— can be used, for example.

The permittivity of the block insulating region 12d is preferably higher than the permittivity of the tunnel insulating region 12a.

Next, a method of manufacturing the nonvolatile semiconductor memory device according to this embodiment is described. The same procedures as those of the first embodiment are carried out until the charge storing region 12c is formed.

After the formation of the charge storing region 12c, the block insulating region 12d that contains molecules or molecular chains with a larger molecular weight than that of the alkyl chains of the tunnel insulating region 12a is formed. The block insulating region 12d may be formed by a liquid phase technique or a gas phase technique. The block insulating region 12d may also be formed in a self-assembling manner with respect to the charge storing region 12c.

According to this embodiment, the organic layer also has the function of a block insulating film, and the thickness of the film structure of each memory cell can be reduced. Thus, the memory cells can be made even smaller, and a scaled down nonvolatile semiconductor memory device can be realized.

### Third Embodiment

A nonvolatile semiconductor memory device according to this embodiment differs from that of the first embodiment in being a three-dimensional device utilizing the so-called BiCS (Bit-Cost Scalable) technique. The structure between the semiconductor layer and the gate electrode is the same as that of the second embodiment. Therefore, the same explanations as those in the second embodiment will not be repeated.

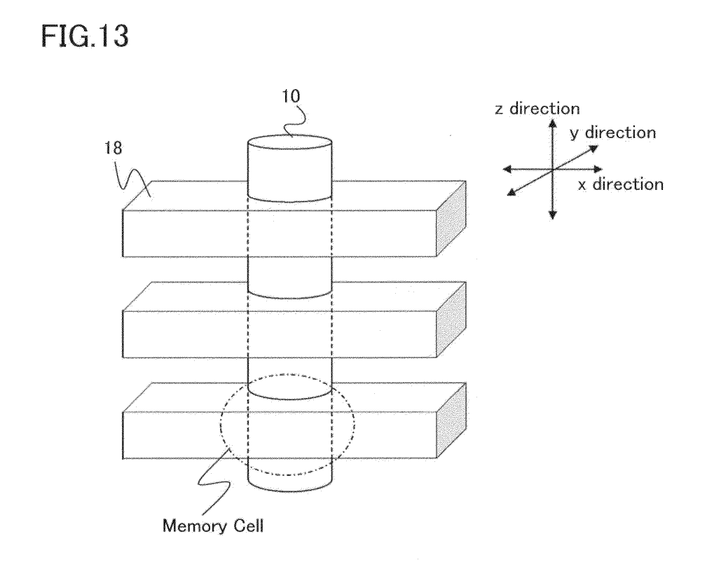

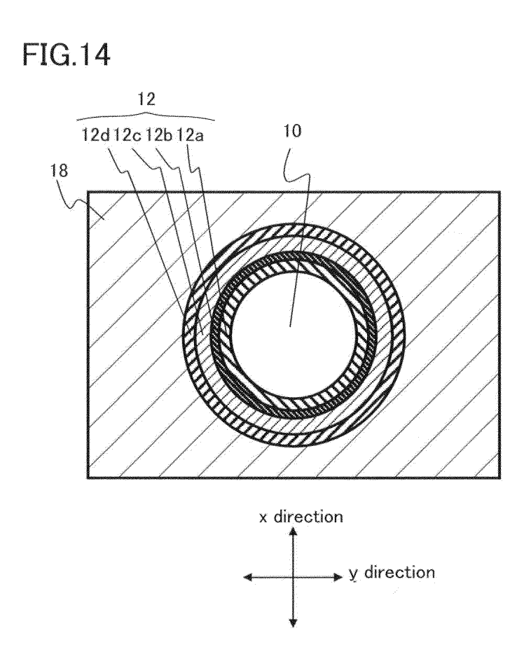

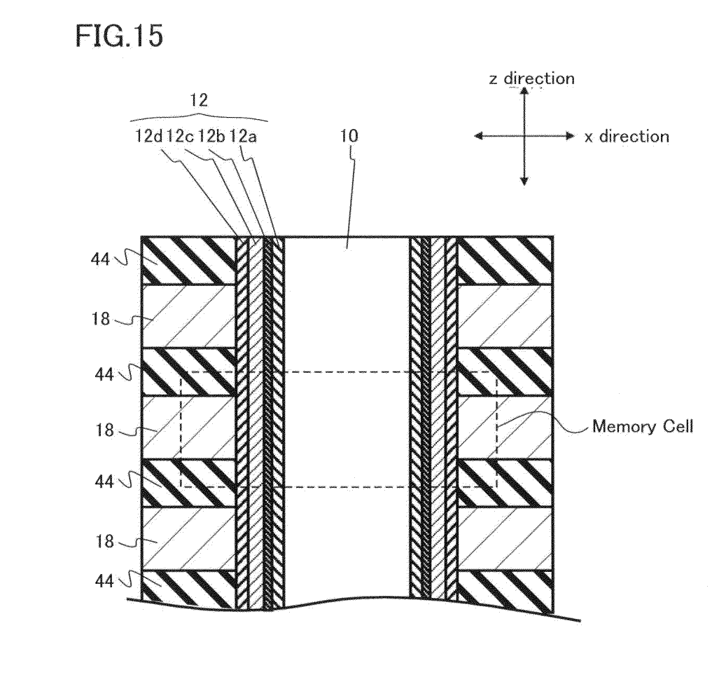

FIG. 13 is a three-dimensional conceptual diagram of the nonvolatile semiconductor memory device of this embodiment. FIG. 14 is an X-Y cross-sectional view of the nonvolatile semiconductor memory device of FIG. 13. FIG. 15 is a X-Z cross-sectional view of the nonvolatile semiconductor memory device of FIG. 13.

In the nonvolatile semiconductor memory device of this embodiment, an insulating layer 44 is formed on a substrate (not shown), and further, gate electrodes 18 and insulating layers 44 are alternately stacked.

In the direction in which the gate electrodes 18 and the insulating layers 44 are stacked, a columnar semiconductor layer 10 is formed to extend from the uppermost surface of the insulating layers 44 toward the substrate. An organic molecular layer 12 is formed between the columnar semiconductor layer 10, and the gate electrodes 18 and the insulating layers 44.

In each of FIGS. 13 and 15, the region surrounded by a dashed line is a memory cell. Each of the memory cells has a structure in which the organic molecular layer 12 is formed on the semiconductor layer 10, and a gate electrode 18 is formed on the organic molecular layer 12.

As in the second embodiment, the organic molecular layer 12 includes a tunnel insulating region 12a of alkyl chains each having one end bonded to the semiconductor layer 10, a charge storing region 12c, a bonding region 12b bonding the other end of each of the alkyl chains to the charge storing region 12c, and a block insulating region 12d formed on the charge storing region 12c. The organic molecular layer 12 is preferably a monomolecular layer, so as to have a smaller thickness and restrain variations in characteristics among the memory cells by achieving uniform characteristics.

The block insulating region 12d has a function to block the electron/hole flow between the charge storing region 12c and the gate electrode 18. The block insulating region 12d contains molecules or molecular chains with a larger molecular weight than that of the alkyl chains forming the tunnel insulating region 12a. The block insulating region 12d has a higher ability to block electron/hole transfers than the tunnel insulating region 12a, by containing molecules or molecular chains with a larger molecular weight than that of the alkyl chains.

Next, a first method of manufacturing the nonvolatile semiconductor memory device according to this embodiment is described. The first method of manufacturing the nonvolatile semiconductor memory device according to this embodiment includes: forming a stack structure by alternately stacking insulating layers and conductive layers; forming a hole that extends in the stacking direction of the stack structure, and penetrates through the insulating layers and the conductive layers; forming a sacrifice film on the inner surface of the hole in such a manner as not to completely fill the hole; forming a semiconductor layer on the sacrifice film formed on the inner surface of the hole; selectively removing the sacrifice film; forming a charge storing region by bonding one end of each of alkyl chains to the semiconductor layer in a self-assembling manner, each of the alkyl chains having a first reactive group at the other end thereof, and by bonding charge storing molecular chains having second reactive groups to the alkyl chains through reactions between the first reactive groups and the second reactive groups; and bonding molecules having a larger molecular weight than a molecular weight of the alkyl chains onto the charge storing unit.

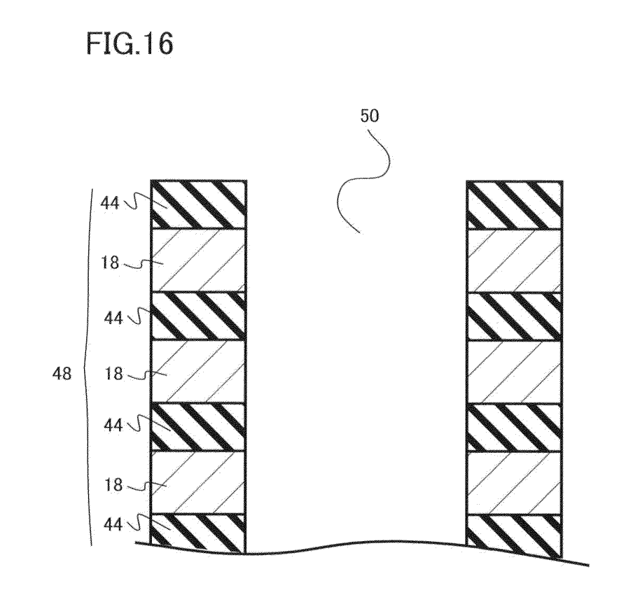

FIGS. 16 through 20 are cross-sectional views illustrating the process according to the method of manufacturing the nonvolatile semiconductor memory device of this embodiment.

First, for example, the insulating layers 44 that are silicon oxide films, and the polycrystalline-silicon conductive layers (the gate electrodes) 18 doped with impurities are alternately stacked, to form a stack structure 48. A hole 50 that extends in the stacking direction of the stack structure 48 and penetrates through the insulating layers 44 and the conductive layers 18 is then formed (FIG. 16).

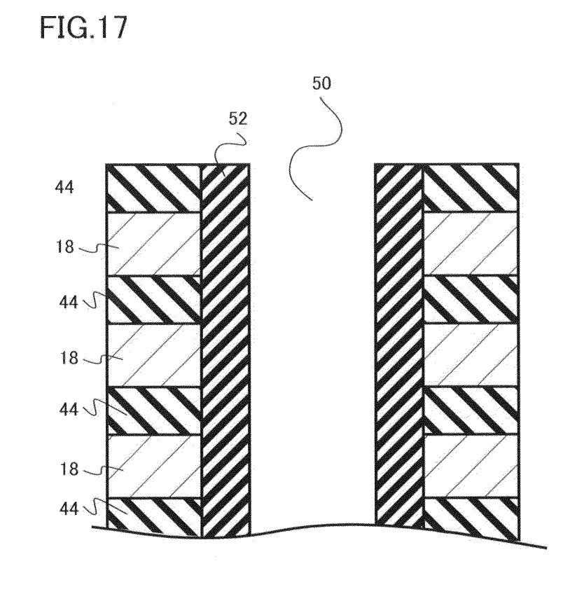

A sacrifice film 52 that is a silicon nitride film, for example, is formed along the inner surface of the hole 50 by CVD, so as not to completely fill the hole 50 (FIG. 17).

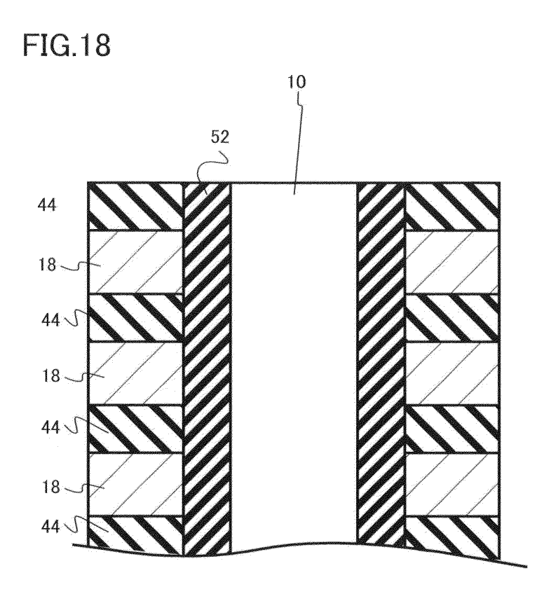

The polycrystalline-silicon semiconductor layer 10 doped with impurities, for example, is then formed by CVD on the sacrifice film 52 formed along the inner surface of the hole 50. The semiconductor layer 10 completely fill the hole 50, for example (FIG. 18).

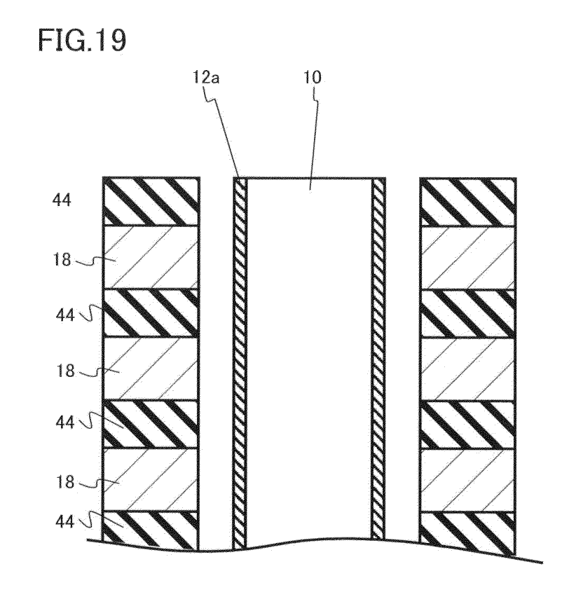

The sacrifice film 52 is then selectively removed by wet etching, for example. The other end of each alkyl chain having the first reactive group at the one end is bonded to the semiconductor layer 10 in a self-assembling manner. In this manner, the tunnel insulating region 12a is formed on the semiconductor layer 10 (FIG. 19). The first reactive groups are azyl groups, for example.

When the alkyl chains are bonded to the semiconductor layer 10 in a self-assembling manner, the bonding preferably involves oxygen atoms (O) to reduce distortions in the bonds due to differences in bond distance and differences in bond angle. Therefore, it is preferable to provide reactive groups containing oxygen, such as —Si(OMe)₃, at the other ends of the alkyl chains, for example. Additionally, prior to the bonding, a silicon oxide film is preferably formed on the surface of the semiconductor layer 10. With the bonding involving oxygen, the formation of the tunnel insulating film 12a can be restrained from depending on the plane orientation of the semiconductor layer 10 located under the tunnel insulating region 12a, even though the semiconductor layer 10 is formed with polycrystals.

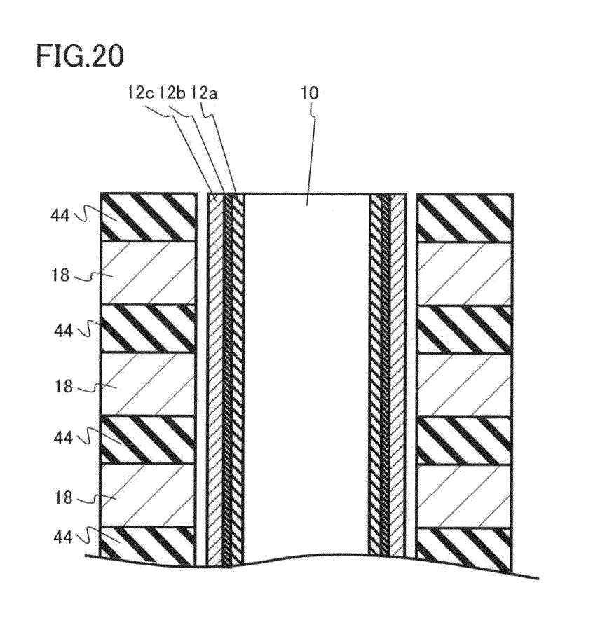

Reactions are then caused between the first reactive groups and the second reactive groups, so that the charge storing molecular chains having the second reactive groups are bonded to the alkyl chains of the tunnel insulating region 12a In this manner, the bonding region 12b and the charge storing region 12c are formed (FIG. 20). The second reactive groups are ethynyl groups, for example. The charge storing molecular chains are porphyrins, for example.

Molecular chains with a larger molecular weight than that of the alkyl chains are then bonded onto the charge storing region 12c. As a result, the block insulating region 12d is formed. The block insulating region 12d is preferably formed in a self-assembling manner, so as to form a uniform and high-density film.

By the above described manufacturing method, the nonvolatile semiconductor memory device illustrated in FIGS. 13 through 15 is manufactured.

Next, a second manufacturing method according to this embodiment is described. The same procedures as those of the above described first manufacturing method are carried out until the charge storing region 12c is formed.

According to this manufacturing method, molecular chains having a larger molecular weight than that of the alkyl chains are bonded onto the conductive layer (the gate electrode) 18, to form the block insulating region 12d. The block insulating region 12d is preferably formed onto the conductive layer (the gate electrode) 18 in a self-assembling manner, so as to form a uniform and high-density film.

To form the block insulating region 12d in a self-assembling manner, silyl groups or derivatives thereof, for example, are provided at respective ends of the molecular chains to be bonded, where the gate electrode 18 is made of polycrystalline silicon. In a case where the gate electrode 18 is made of a metal such as gold (Au), silver (Ag), copper (Cu), tungsten (W), tungsten nitride (WN), tantalum nitride (TaN), or titanium nitride (TiN), thiol groups, for example, are provided at respective ends of the molecular chains to be bonded. Ina case where the gate electrode 18 is made of a metal such as tungsten (W), tungsten nitride (WN), tantalum (Ta), tantalum nitride (TaN), molybdenum (Mo), molybdenum nitride (MoN), or titanium nitride (TiN), alcohol groups or carboxyl groups, for example, are provided at respective ends of the molecular chains to be bonded.

According to this manufacturing method, the block insulating region 12d is formed after the tunnel insulating region 12a, the bonding region 12b, and the charge storing region 12c are formed. However, the tunnel insulating region 12a, the bonding region 12b, and the charge storing region 12c may be formed after the block insulating region 12d is formed on the conductive layer (the gate electrode) 18 in a self-assembling manner.

According to this embodiment, three-dimensional memory cells are formed, to increase the degree of memory cell integration. With this structure, a nonvolatile semiconductor memory device having a higher storage capacity than that of the second embodiment can be realized. In the BiCS structure of this embodiment, the reduction in the thickness of the film structure of each memory cell leads directly to the higher degree of memory integration. Thus, the film structure of this embodiment in which the organic molecular layer 12 has all the functions of a tunnel insulating film, a charge storing layer, and a block insulating film is highly beneficial.

### EXAMPLES

In the following, examples are described.

### Example

A film structure according to the first embodiment is formed and evaluated.

As the molecules for the alkyl chains to form the tunnel insulating region 12a, molecules N₃(CH₂)₁₂SiCl₃ each having a derivative of a silyl group at one end and an azido group at the other end and formed with 12 carbons are prepared. The molecules are formed with 12 carbons. Using the molecules, a 5-nm silicon oxide film is formed on a clean p-type silicon substrate through thermal oxidation. The substrate is then irradiated with UV, to grow a self-assembled monolayer (SAM).

To form the charge storing region 12c, the silicon substrate is immersed in a solution of molecules having ethynyl groups added to porphyrins, to form porphyrins chemically bonded onto the alkyl chains. Only functional group reactions are caused between the ethynyl groups and the azido groups through Huisgen reactions, and triazole rings are formed by the bonding. This can be confirmed through infrared absorption spectra. A 10-nm silicon oxide film is formed thereon by ALD, and Al is deposited on the silicon oxide film, to form an electrode and complete the sample.

A voltage generated by superimposing a direct-current voltage V on an alternating-current voltage having low amplitude is applied between the p-type silicon substrate (hereinafter referred to as the substrate electrode) and the Al electrode (hereinafter referred to as the gate electrode) of the sample, and the current component at 90 degrees with respect to the voltage in terms of phase is measured, to determine the relationship between the capacity C of the sample and the direct-current voltage V (hereinafter referred to as the C-V characteristics). From the C-V characteristics, it is possible to measure the potential difference between the gate electrode and the substrate electrode (hereinafter referred to as the gate voltage) when the charges are neutral in the interface between the silicon substrate and the oxide film.

This gate voltage is known as the flat band voltage. When there exist charges between the substrate electrode and the gate electrode, the flat band voltage varies, because voltage is required for neutralizing the line of electric force generated from the charges.

When a voltage for allowing charge injection into the charge storing region 12c (hereinafter referred to as the write voltage) is applied as the gate voltage, the flat band voltage varies in proportion to the amount of charges injected into the charge storing region 12c. By measuring the changes caused in the flat band voltage before and after the application of the write voltage, the amount of charges injected into the charge storing region 12c can be measured.

In this example, the charge amount stored in the molecular layer is estimated to be 10¹³/cm² or more, based on the change in the flat band voltage.

### Comparative Example

Molecules each having an alkyl chain formed with 12 carbons as an insulating unit are used to grow a self-assembled monolayer on a clean p-type silicon substrate having a 5-nm silicon oxide film formed thereon through thermal oxidation. One end of each alkyl chain has a porphyrin as part of the charge storing unit, and the other end has a derivative of a silyl group.

A 10-nm silicon oxide film is formed thereon by ALD, and Al is deposited on the silicon oxide film, to form an electrode and complete a sample. The same measurement as in the example is carried out, and the charge amount is estimated to be approximately 10¹²/cm².

In this manner, it is confirmed that the amount of stored charges can be increased by the method used in the example.

While certain embodiments have been described, these embodiments have been presented by way of example only, and are not intended to limit the scope of the inventions. Indeed, the nonvolatile semiconductor memory devices and the methods of manufacturing the nonvolatile semiconductor memory devices described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device comprising:
a semiconductor layer;
an organic molecular layer formed on the semiconductor layer, the organic molecular layer including a plurality of organic molecules, each of the organic molecules includes a tunnel insulating unit of an alkyl chain having one end bonded to the semiconductor layer, a charge storing unit, and a bonding unit configured to bond the other end of the alkyl chain to the charge storing unit;
a block insulating film formed on the organic molecular layer; and
a gate electrode formed on the block insulating film.

2. The device according to claim 1, wherein the bonding unit is a triazole ring.

3. The device according to claim 1, wherein the number of carbons in the alkyl chain is not smaller than 6 and not larger than 30.

4. A nonvolatile semiconductor memory device comprising:
a semiconductor layer;
an organic molecular layer formed on the semiconductor layer, the organic molecular layer including a plurality of organic molecules, each of the organic molecules includes a tunnel insulating unit of an alkyl chain having one end bonded to the semiconductor layer, a charge storing unit, a bonding unit configured to bond the other end of the alkyl chain to the charge storing unit; the organic molecular layer including a block insulating region formed on the charge storing unit;
a gate electrode formed above the organic molecular layer; and
the block insulating region formed between the organic molecular layer and the gate electrode, and including a plurality of block insulating molecular chains, each of the block insulating molecular chains having a larger molecular weight than a molecular weight of the alkyl chain.

5. The device according to claim 4, wherein the bonding unit is a triazole ring.

6. The device according to claim 4, wherein the block insulating molecular chain is an alkyl halide molecular chain.

7. The device according to claim 4, wherein the number of carbons in the alkyl chain is not smaller than 6 and not larger than 30.

8. The device according to claim 4, wherein the block insulating molecular chain bonds to the charge storing unit.

9. The device according to claim 4, wherein the block insulating molecular chain bonds to the gate electrode.

10. A method of manufacturing a nonvolatile semiconductor memory device, comprising:
bonding one end of each of alkyl chains to a semiconductor layer in a self-assembling manner, each of the alkyl chains having a first reactive group at the other end thereof;
forming a charge storing region by bonding charge storing molecular chains having second reactive groups to the alkyl chains through reactions between the first reactive groups and the second reactive groups;
forming a block insulating film on the charge storing unit; and
forming a gate electrode on the block insulating film.

11. The method according to claim 10, wherein the first reactive groups and the second reactive groups are azido groups and ethynyl groups, respectively, or ethynyl groups and azido groups, respectively.

12. The method according to claim 10, wherein the number of carbons in each of the alkyl chains is not smaller than 6 and not larger than 30.

13. A method of manufacturing a nonvolatile semiconductor memory device, comprising:
forming a stack structure by alternately stacking insulating layers and conductive layers;
forming a hole that extends in a stacking direction of the stack structure, and penetrates through the insulating layers and the conductive layers;
forming a sacrifice film along an inner surface of the hole;
forming a semiconductor layer on the sacrifice film formed along the inner surface of the hole;
selectively removing the sacrifice film;
bonding one end of each of alkyl chains to the semiconductor layer in a self-assembling manner, each of the alkyl chains having a first reactive group at the other end thereof;
forming a charge storing region by bonding charge storing molecular chains having second reactive groups to the alkyl chains through reactions between the first reactive groups and the second reactive groups; and
bonding block insulating molecular chains having a larger molecular weight than a molecular weight of the alkyl chains to the charge storing molecular chains.

14. The method according to claim 13, wherein the first reactive groups and the second reactive groups are azido groups and ethynyl groups, respectively, or ethynyl groups and azido groups, respectively.

15. The method according to claim 13, wherein the number of carbons in each of the alkyl chains is not smaller than 6 and not larger than 30.

16. The method according to claim 13, wherein the block insulating molecular chains are alkyl halide molecular chains.

17. A method of manufacturing a nonvolatile semiconductor memory device, comprising:
forming a stack structure by alternately stacking insulating layers and conductive layers;
forming a hole that extends in a stacking direction of the stack structure, and penetrates through the insulating layers and the conductive layers;
forming a sacrifice film along an inner surface of the hole;
forming a semiconductor layer on the sacrifice film formed along the inner surface of the hole;
selectively removing the sacrifice film;
bonding one end of each of alkyl chains to the semiconductor layer in a self-assembling manner, each of the alkyl chains having a first reactive group at the other end thereof;
forming a charge storing region by bonding charge storing molecular chains having second reactive groups to the alkyl chains through reactions between the first reactive groups and the second reactive groups; and
bonding block insulating molecular chains having a larger molecular weight than a molecular weight of the alkyl chains onto an inner surface of the conductive layers.

18. The method according to claim 17, wherein the first reactive groups and the second reactive groups are azido groups and ethynyl groups, respectively, or ethynyl groups and azido groups, respectively.

19. The method according to claim 17, wherein the number of carbons in each of the alkyl chains is not smaller than 6 and not larger than 30.

20. The method according to claim 17, wherein the block insulating molecular chains are alkyl halide molecular chains.
